(19) United States
(12) Patent Application Publication
(10) Pub. No.: US 2026/0338929 A1
(43) Pub. Date: Oct. 29, 2026

(54) TECHNIQUES FOR SIMULATING ELECTRO-OPTICAL BEHAVIOR IN A CIRCUIT

(71) Applicant: AEVA, INC., Mountain View, CA (US)

(72) Inventors: Eric Bohannon, Henrietta, NY (US); Garret Phillips, Pittsford, NY (US); Bryce Bradford, Cupertino, CA (US)

(21) Appl. No.: 19/390,355

(22) Filed: Nov. 14, 2025

Related U.S. Application Data
(63) Continuation of application No. 18/062,418, filed on Dec. 6, 2022.

(51) Int. Cl. G01S 7/497; G01S 7/4913; G01S 17/32; G01S 17/58; H03L 7/099

(52) U.S. Cl. CPC G01S 7/497; G01S 7/4913; G01S 17/32; G01S 17/58; H03L 7/099

(57) ABSTRACT

A laser diode control system for a frequency modulated continuous wave (FMCW) light detection and ranging (LIDAR) system includes a laser configured to output a beam; a modulator operatively coupled to the laser and configured to frequency modulate the beam; an interferometer operatively coupled to the laser and configured to measure deviations in the frequency modulation of the beam; and correction circuitry configured to: generate a correction signal based on the deviations in the frequency modulation of the beam; and apply the correction signal to the modulator to adjust the frequency modulation of the beam based at least in part on the deviations in the frequency modulation of the beam.

### CROSS REFERENCE TO RELATED APPLICATIONS

This application is a continuation of U.S. Application No. 18/062,418, filed Dec. 6, 2022 and entitled “TECHNIQUES FOR SIMULATING ELECTRO-OPTICAL BEHAVIOR IN A CIRCUIT,” which is hereby incorporated by reference in its entirety.

### FIELD

The present disclosure is related to LIDAR (light detection and ranging) systems in general, and more particularly to mimicking electro-optical behavior in a circuit for testing, monitoring, and optimizing components of the circuit.

### BACKGROUND

Frequency-Modulated Continuous-Wave (FMCW) LIDAR systems use tunable, infrared lasers for frequency-chirped illumination of targets, and coherent receivers for detection of backscattered or reflected light from the targets that are combined with a local copy of the transmitted signal. Mixing the local copy with the return signal, delayed by the round-trip time to the target and back, generates signals at the receiver with frequencies that are proportional to the distance to each target in the field of view of the system. Electrical components and photonics components can be incorporated into one or more chips for use in a LIDAR system.

### SUMMARY

The present disclosure describes examples of a system, apparatus, and method for mimicking electro-optical behavior in a circuit.

In some embodiments, a laser diode control system for a frequency modulated continuous wave (FMCW) light detection and ranging (LIDAR) system includes circuitry to produce a phase locked loop. The phase locked loop includes one or more integrated electronics components and an electronic circuit coupled to the one or more integrated electronics components. The electronic circuit may be configured to receive an input signal from the one or more integrated electronics components and produce a feedback signal to mimic operation of one or more photonics components to test operation of the integrated electronic components of the phase locked loop.

In some embodiments, the electronic circuit comprises at least a voltage-controlled oscillator (VCO), differentiator, and an envelope detector. In some embodiments, the VCO generates a signal with frequency that is dependent on a voltage produced by the one or more integrated electronic components, the differentiator produces a phase delayed signal from the VCO signal, and the envelope detector produces an output beat frequency from the phase delayed signal and the VCO signal. In some embodiments, the electronic circuit includes at least a voltage-controlled oscillator (VCO), a time delay, and quadrature processing. In some embodiments, the VCO generates a signal with frequency that is dependent on a voltage produced by the one or more integrated electronic components, the differentiator produces a phase delayed signal from the VCO signal, and the quadrature processing produces a beat frequency from the phase delayed signal and the VCO signal.

In some embodiments, the one or more integrated electronics components include at least one of a phase frequency detector (PFD) and charge pump, a loop filter, a digital integrator, or an amplifier. In some embodiments, the electronic circuit operates to validate functionality of the one or more integrated electronic components. In some embodiments, the electronics circuit is replaceable by one or more photonics components upon validation of the one or more integrated electronic components. In some embodiments, the laser diode control system includes an optical source that generates a frequency modulated continuous wave (FMCW) optical beam for determining range and velocity of a target.

In some embodiments, a light detection and ranging (LIDAR) system, includes circuitry to produce a phase locked loop. The phase locked loop includes one or more integrated electronics components and an electronic circuit coupled to the one or more integrated electronics components. The electronic circuit may be configured to receive an input signal from the one or more integrated electronics components and produce a feedback signal to mimic operation of one or more photonics components to test operation of the integrated electronic components of the phase locked loop.

In some embodiments, a method includes providing an electronic circuit within a laser diode control system, receiving, by the electronic circuit, an input signal from one or more integrated electronic components of the laser diode control system, and producing, by the electronic circuit, a feedback signal to mimic operation of one or more photonics components to test operation of the integrated electronic components.

In some embodiments, the method further includes validating functionality of the one or more integrated electronic components based on the feedback signal from the electronic circuit, and in response to validating the functionality of the one or more integrated electronic components, replacing the electronic circuit with one or more photonics devices.

### BRIEF DESCRIPTION OF THE DRAWINGS

For a more complete understanding of various examples, reference is now made to the following detailed description taken in connection with the accompanying drawings in which like identifiers correspond to like elements:

FIG. 1 is a block diagram illustrating an example LIDAR system according to embodiments of the present disclosure;

FIG. 2 is a time-frequency diagram illustrating one example of LIDAR waveforms according to embodiments of the present disclosure;

FIG. 3 is a block diagram illustrating a circuit providing a phase locked loop for driving a laser diode according to embodiments of the present disclosure;

FIG. 4 is a block diagram illustrating an example circuit including circuitry to simulate operation of photonics components according to embodiments of the present disclosure;

FIG. 5 is a block diagram illustrating another example circuit including circuitry to simulate operation of photonics components according to embodiments of the present disclosure;

FIG. 6 is a block diagram illustrating another example circuit including circuitry to simulate operation of photonics components according to embodiments of the present disclosure;

FIG. 7 is a block diagram illustrating another example circuit including circuitry to simulate operation of photonics components in parallel with the photonics components according to embodiments of the present disclosure;

FIG. 8 is a block diagram illustrating another example circuit including circuitry to simulate operation of photonics components in parallel with the photonics components according to embodiments of the present disclosure; and

FIG. 9 is a flow diagram of a method of operating a circuit including photonics simulating circuitry to test electronic components of the circuit according to embodiments of the present disclosure.

### DETAILED DESCRIPTION

The present disclosure describes various examples of circuitry for mimicking electro-optical behavior in a circuit. According to some embodiments, the described LIDAR system described herein may be implemented in any sensing market, such as, but not limited to, transportation, manufacturing, metrology, medical, virtual reality, augmented reality, and security systems. According to some embodiments, the described LIDAR system is implemented as part of a front-end of frequency modulated continuous-wave (FMCW) device that assists with spatial awareness for automated driver assist systems, or self-driving vehicles.

An electro-optical phase locked loop can be used for driving and controlling a laser diode. Such a loop contains electronic components and photonics components. Conventional systems lack the ability to validate functionality of on-chip electrical components in the absence of the photonics components of the circuit. Additionally, conventional systems may be unable to monitor electronic components separate from photonics components of a circuit (e.g., for optimization, troubleshooting, or diagnosis of issues).

Embodiments of the present disclosure address the issues of testing, optimizing, and monitoring of electrical components of an electro-optical circuit without the photonics components by mimicking the photonics components with electrical circuitry. To validate functionality of on-chip electronic components in the absence of photonics components, embodiments incorporate an electronic circuit including components that receive an input signal and provide an output signal that mimics or represents a signal that would be produced by the photonics components. For example, the electronic circuit to mimic the photonics components can receive the photonics optical circuits input laser drive signal. The electronic circuit would generate an oscillating wave having a differential voltage or differential current dependent frequency, and output a beat frequency simulating the photonics optical circuits output. Accordingly, problems associated with the electronic components and circuits can potentially be identified and addressed prior to incorporation with the photonics components. Thus, embodiments provide for test time savings and reduced cost because the electronics are screened in an on-chip loop prior to incorporation of photonics components. Additionally, embodiments provide for the ability to monitor and optimize the electronic components after incorporation of the photonics components.

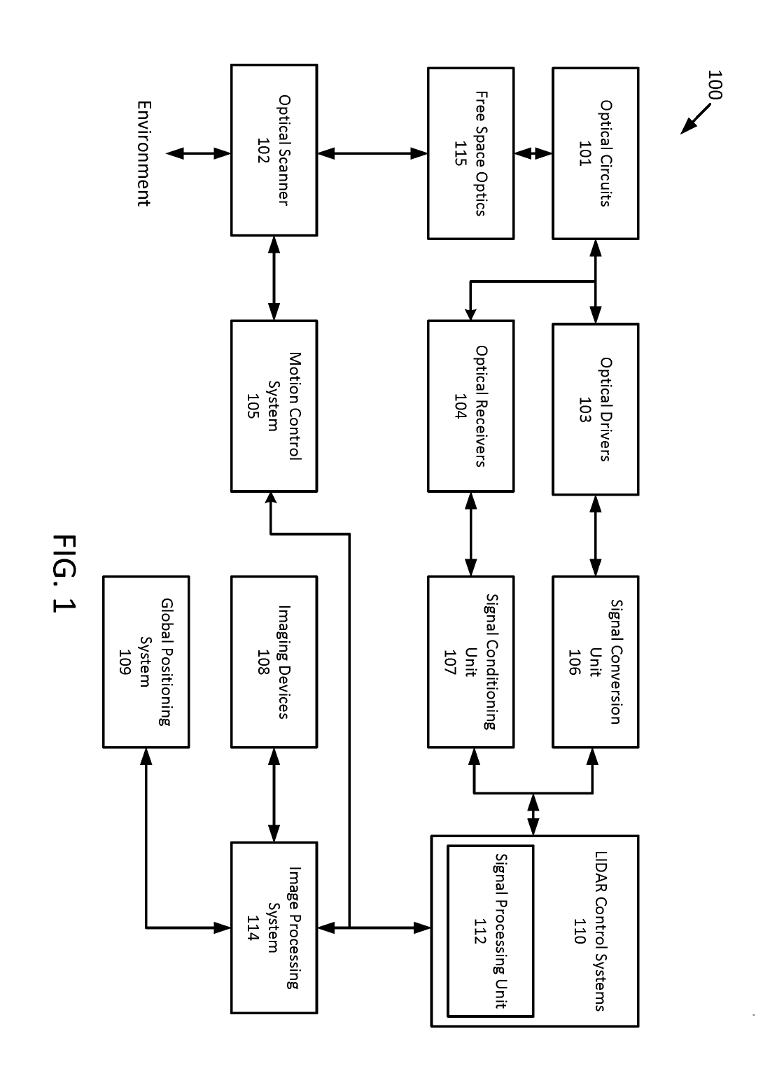

FIG. 1 illustrates a LIDAR system 100 according to example implementations of the present disclosure. The LIDAR system 100 includes one or more of each of a number of components but may include fewer or additional components than shown in FIG. 1. One or more of the components depicted in FIG. 1 can be implemented on a photonics chip, according to some embodiments. The optical circuits 101 may include a combination of active optical components and passive optical components. Active optical components may generate, amplify, and/or detect optical signals and the like. In some examples, the active optical component includes optical beams at different wavelengths, and includes one or more optical amplifiers, one or more optical detectors, or the like.

Free space optics 115 may include one or more optical waveguides to carry optical signals, and route and manipulate optical signals to appropriate input / output ports of the active optical circuit. The free space optics 115 may also include one or more optical components such as taps, wavelength division multiplexers (WDM), splitters/combiners, polarization beam splitters (PBS), collimators, couplers or the like. In some examples, the free space optics 115 may include components to transform the polarization state and direct received polarized light to optical detectors using a PBS, for example. The free space optics 115 may further include a diffractive element to deflect optical beams having different frequencies at different angles along an axis (e.g., a fast-axis).

In some examples, the LIDAR system 100 includes an optical scanner 102 that includes one or more scanning mirrors that are rotatable along an axis (e.g., a slow-axis) that is orthogonal or substantially orthogonal to the fast-axis of the diffractive element to steer optical signals to scan an environment according to a scanning pattern. For instance, the scanning mirrors may be rotatable by one or more galvanometers. Objects in the target environment may scatter an incident light into a return optical beam or a target return signal. The optical scanner 102 also collects the return optical beam or the target return signal, which may be returned to the passive optical circuit component of the optical circuits 101. For example, the return optical beam may be directed to an optical detector by a polarization beam splitter. In addition to the mirrors and galvanometers, the optical scanner 102 may include components such as a quarter-wave plate, lens, anti-reflective coated window or the like.

To control and support the optical circuits 101 and optical scanner 102, the LIDAR system 100 includes LIDAR control systems 110. The LIDAR control systems 110 may include a processing device for the LIDAR system 100. In some examples, the processing device may be one or more general-purpose processing devices such as a microprocessor, central processing unit, or the like. More particularly, the processing device may be complex instruction set computing (CISC) microprocessor, reduced instruction set computer (RISC) microprocessor, very long instruction word (VLIW) microprocessor, or processor implementing other instruction sets, or processors implementing a combination of instruction sets. The processing device may also be one or more special-purpose processing devices such as an application specific integrated circuit (ASIC), a field programmable gate array (FPGA), a digital signal processor (DSP), network processor, or the like.

In some examples, the LIDAR control systems 110 may include a signal processing unit 112 such as a DSP. The LIDAR control systems 110 are configured to output digital control signals to control optical drivers 103. In some examples, the digital control signals may be converted to analog signals through signal conversion unit 106. For example, the signal conversion unit 106 may include a digital-to-analog converter. The optical drivers 103 may then provide drive signals to active optical components of optical circuits 101 to drive optical sources such as lasers and amplifiers. In some examples, several optical drivers 103 and signal conversion units 106 may be provided to drive multiple optical sources.

The LIDAR control systems 110 are also configured to output digital control signals for the optical scanner 102. A motion control system 105 may control the galvanometers of the optical scanner 102 based on control signals received from the LIDAR control systems 110. For example, a digital-to-analog converter may convert coordinate routing information from the LIDAR control systems 110 to signals interpretable by the galvanometers in the optical scanner 102. In some examples, a motion control system 105 may also return information to the LIDAR control systems 110 about the position or operation of components of the optical scanner 102. For example, an analog-to-digital converter may in turn convert information about the galvanometers’ position to a signal interpretable by the LIDAR control systems 110.

The LIDAR control systems 110 are further configured to analyze incoming digital signals. In this regard, the LIDAR system 100 includes optical receivers 104 to measure one or more beams received by optical circuits 101. For example, a reference beam receiver may measure the amplitude of a reference beam from the active optical component, and an analog-to-digital converter converts signals from the reference receiver to signals interpretable by the LIDAR control systems 110. Target receivers measure the optical signal that carries information about the range and velocity of a target in the form of a beat frequency, modulated optical signal. The reflected beam may be mixed with a second signal from a local oscillator. The optical receivers 104 may include a high-speed analog-to-digital converter to convert signals from the target receiver to signals interpretable by the LIDAR control systems 110. In some examples, the signals from the optical receivers 104 may be subject to signal conditioning by signal conditioning unit 107 prior to receipt by the LIDAR control systems 110. For example, the signals from the optical receivers 104 may be provided to an operational amplifier for amplification of the received signals and the amplified signals may be provided to the LIDAR control systems 110.

In some applications, the LIDAR system 100 may additionally include one or more imaging devices 108 configured to capture images of the environment, a global positioning system 109 configured to provide a geographic location of the system, or other sensor inputs. The LIDAR system 100 may also include an image processing system 114. The image processing system 114 can be configured to receive the images and geographic location, and send the images and location or information related thereto to the LIDAR control systems 110 or other systems connected to the LIDAR system 100.

In operation according to some examples, the LIDAR system 100 is configured to use nondegenerate optical sources to simultaneously measure range and velocity across two dimensions. This capability allows for real-time, long-range measurements of range, velocity, azimuth, and elevation of the surrounding environment.

In some examples, the scanning process begins with the optical drivers 103 and LIDAR control systems 110. The LIDAR control systems 110 instruct, e.g., via signal processor unit 112, the optical drivers 103 to independently modulate one or more optical beams, and these modulated signals propagate through the optical circuits 101 to the free space optics 115. The free space optics 115 directs the light at the optical scanner 102 that scans a target environment over a preprogrammed pattern defined by the motion control system 105. The optical circuits 101 may also include a polarization wave plate (PWP) to transform the polarization of the light as it leaves the optical circuits 101. In some examples, the polarization wave plate may be a quarter-wave plate or a half-wave plate. A portion of the polarized light may also be reflected back to the optical circuits 101. For example, lensing or collimating systems used in LIDAR system 100 may have natural reflective properties or a reflective coating to reflect a portion of the light back to the optical circuits 101.

Optical signals reflected back from an environment pass through the optical circuits 101 to the optical receivers 104. Because the polarization of the light has been transformed, it may be reflected by a polarization beam splitter along with the portion of polarized light that was reflected back to the optical circuits 101. In such scenarios, rather than returning to the same fiber or waveguide serving as an optical source, the reflected signals can be reflected to separate optical receivers 104. These signals interfere with one another and generate a combined signal. The combined signal can then be reflected to the optical receivers 104. Also, each beam signal that returns from the target environment may produce a time-shifted waveform. The temporal phase difference between the two waveforms generates a beat frequency measured on the optical receivers 104 (e.g., photodetectors).

The analog signals from the optical receivers 104 are converted to digital signals by the signal conditioning unit 107. These digital signals are then sent to the LIDAR control systems 110. A signal processing unit 112 may then receive the digital signals to further process and interpret them. In some embodiments, the signal processing unit 112 also receives position data from the motion control system 105 and galvanometers (not shown) as well as image data from the image processing system 114. The signal processing unit 112 can then generate 3D point cloud data that includes information about range and/or velocity points in the target environment as the optical scanner 102 scans additional points. The signal processing unit 112 can also overlay 3D point cloud data with image data to determine velocity and/or distance of objects in the surrounding area. The signal processing unit 112 also processes the satellite-based navigation location data to provide data related to a specific global location.

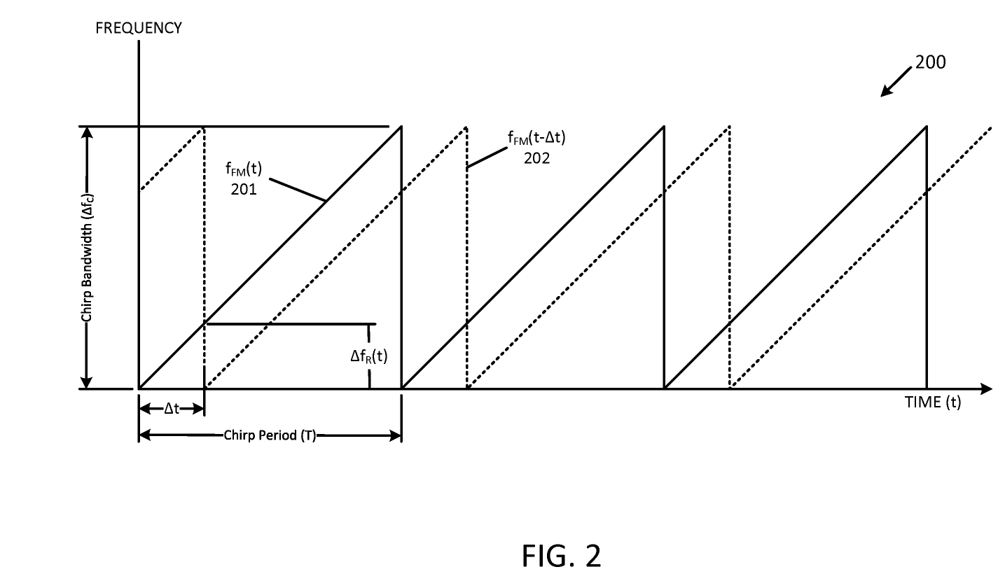

FIG. 2 is a time-frequency diagram 200 of an FMCW scanning signal 201 that can be used by a LIDAR system, such as system 100, to scan a target environment according to some embodiments. In one example, the scanning waveform 201, labeled as f_{FM}(t), is a sawtooth waveform (sawtooth “chirp”) with a chirp bandwidth Δf_{C} and a chirp period T_{C}. The slope of the sawtooth is given as k = (Δf_{C}/T_{C}). FIG. 2 also depicts target return signal 202 according to some embodiments. Target return signal 202, labeled as f_{FM}(t-Δt), is a time-delayed version of the scanning signal 201, where Δt is the round trip time to and from a target illuminated by scanning signal 201. The round trip time is given as Δt = 2R/v, where R is the target range and v is the velocity of the optical beam, which is the speed of light c. The target range, R, can therefore be calculated as R = c(Δt/2). When the return signal 202 is optically mixed with the scanning signal, a range dependent difference frequency (“beat frequency”) Δf_{R}(t) is generated. The beat frequency Δf_{R}(t)is linearly related to the time delay Δt by the slope of the sawtooth k. That is, Δf_{R}(t)= kΔt. Since the target range R is proportional to Δt, the target range R can be calculated as R = (c/2)(Δf_{R}(t)/k). That is, the range R is linearly related to the beat frequency Δf_{R}(t). The beat frequency Δf_{R}(t)can be generated, for example, as an analog signal in optical receivers 104 of system 100. The beat frequency can then be digitized by an analog-to-digital converter (ADC), for example, in a signal conditioning unit such as signal conditioning unit 107 in LIDAR system 100. The digitized beat frequency signal can then be digitally processed, for example, in a signal processing unit, such as signal processing unit 112 in system 100. It should be noted that the target return signal 202 will, in general, also includes a frequency offset (Doppler shift) if the target has a velocity relative to the LIDAR system 100. The Doppler shift can be determined separately, and used to correct the frequency of the return signal, so the Doppler shift is not shown in FIG. 2 for simplicity and ease of explanation. It should also be noted that the sampling frequency of the ADC will determine the highest beat frequency that can be processed by the system without aliasing. In general, the highest frequency that can be processed is one-half of the sampling frequency (i.e., the “Nyquist limit”). In one example, and without limitation, if the sampling frequency of the ADC is 1 gigahertz, then the highest beat frequency that can be processed without aliasing (Δf_{Rmax}) is 500 megahertz. This limit in turn determines the maximum range of the system as Rₘₐₓ = (c/2)(Δf_{Rmax}/k) which can be adjusted by changing the chirp slope k. In one example, while the data samples from the ADC may be continuous, the subsequent digital processing described below may be partitioned into “time segments” that can be associated with some periodicity in the LIDAR system 100. In one example, and without limitation, a time segment might correspond to a predetermined number of chirp periods T, or a number of full rotations in azimuth by the optical scanner.

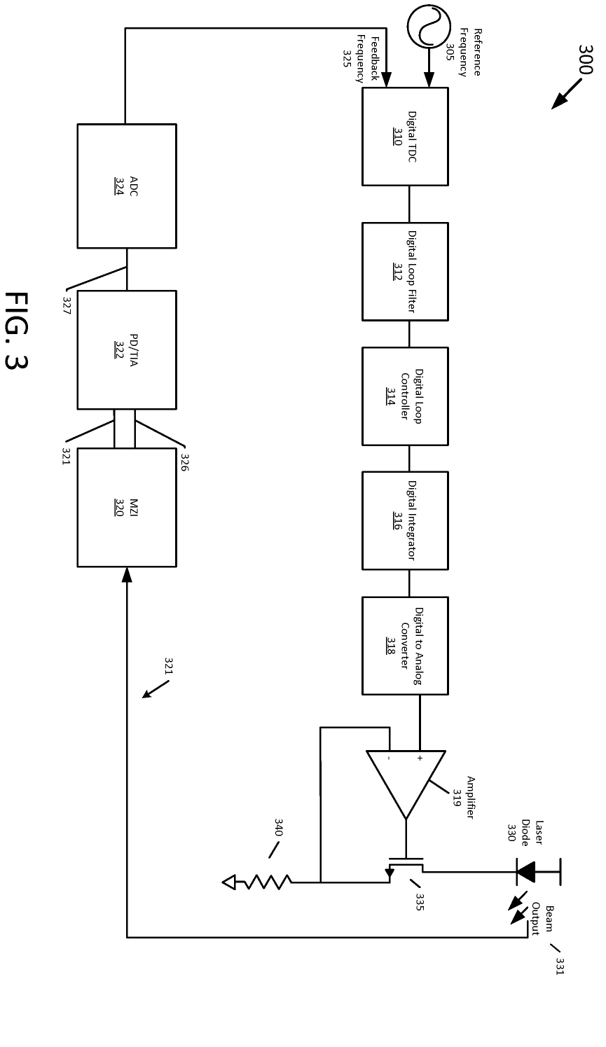

Embodiments described below with respect to FIGS. 3-9 may be used, at least in part, to produce and operate an FMCW LIDAR system as described with respect to FIGS. 1 and 2 above.

FIG. 3 depicts a circuit 300 providing a phase locked loop for driving a frequency modulated laser diode according to some embodiments of the present disclosure. Circuit 300 includes electrical components and photonics components that operate together to generate a frequency chirped output beam from the laser diode 330. The circuit may receive a reference frequency 305 from an oscillator (not depicted) which can include, but is not limited to, a mechanical oscillator, digital oscillator, or other component that generates an oscillating signal. The electronic components of the circuit 300 may include digital time-to-digital converter (TDC) 310, digital loop filter 312, digital loop controller 314, digital integrator 316, digital to analog converter 318, and an amplifier 319 (e.g., an operational amplifier). Additional electronics components that are not depicted may also be incorporated into the circuit 300. Embodiments may also operate with different or fewer electronic components. Additionally, although depicted as separate components, the electronic components may be incorporated into one or more circuits or software, or a combination of circuits and software.

The digital TDC 310 includes the functionality to receive a reference signal (e.g., reference frequency 305) from an oscillator and a feedback signal (e.g., feedback frequency 325) from a feedback loop 321. The digital TDC 310 includes the functionality to measure time intervals associated with the oscillator and feedback loop and convert them into a digital representation of the frequency of the two signals. The digital loop filter 312 includes the functionality to filter out frequencies that are outside the frequencies used for the loop and to stabilize the PLL loop. For example, the digital loop filter 312 may be a high-pass, low-pass, or bandpass filter to remove frequencies outside the intended operational range of the phase-locked loop. The digital loop controller 314 includes the functionality to change the frequency chirp direction (up vs down) of the laser diode. The digital integrator 316 includes the functionality to provide an increasing or decreasing ramp in value that results in a current into the laser diode based on the input control signal. The digital to analog converter 318 includes the functionality to receive a digital signal and convert the digital signal into an analog electrical signal.

The laser diode 330 includes the functionality to generate an output optical beam (e.g., beam output 331) with a frequency that is dependent on a voltage or current produced by the output of the electronic components (e.g., voltage or current produced by a transistor 335/resistor 340 with the output of the electronic components at the gate). Accordingly, the beam output 331 is dependent on the reference frequency 305 as processed by the electronic components. The beam output 331 is transmitted to a Mach-Zehnder Interferometer (MZI) 320 which includes the functionality to introduce at least one temporal delay (e.g., delayed optical beam 326) in the optical beam received from the laser diode 330. The delayed optical beam 326 and the original optical beam (e.g., beam output 331) are then received at the PD/TIA 322 where the beam output 331 and delayed optical beam 326 are combined at a photodetector (PD) included within PD/TIA 322 to produce a beat signal 327. The beat signal 327 is then amplified by a TIA included within PD/TIA 322 and provided to an analog to digital converter (ADC) 324. The output of the ADC 324 may be a digital feedback frequency 325 which is then fed back into the electronic components (e.g., digital TDC 310). Thus, the electronic components and photonics components are provided in a phase-locked loop for modulating the beam output 331 transmitted from the laser diode 330.

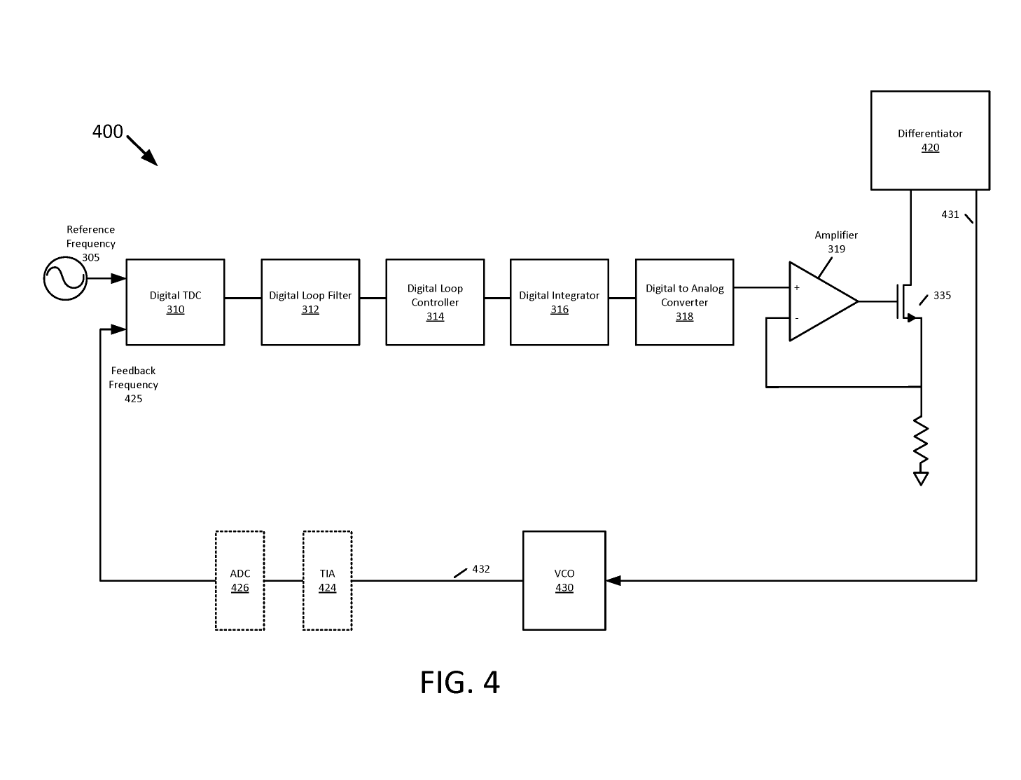

FIG. 4 depicts an example circuit 400 including circuitry to simulate operation of photonics components according to embodiments of the present disclosure. The circuit 400 may include the same or similar electronic components as circuit 300 of FIG. 3 (e.g., digital TDC 310, digital loop filter 312, digital loop controller 314, digital integrator 316, and digital to analog converter 318). As depicted in FIG. 4, rather than a photodiode, MZI, and PD, the circuit 400 may include a differentiator 420, a voltage-controlled oscillator (VCO) 430, , and may include TIA 424 and ADC 426.

The differentiator 420 produces a control voltage 431 proportional to the slope of the current into the laser diode and VCO 430 produces a beat frequency 432 that is proportional to the value of the signal out of the differentiator 420. As such, the differentiator 420 and the VCO 430, and may perform their respective functions in tandem to electrically simulate functions similar to those of photonics (e.g., at least laser diode 330, MZI, 320, and PD 322) by producing an electronic beat frequency from the output of the integrated electronic components (e.g., digital TDC 310, digital loop filter 312, digital loop controller 314, digital integrator 316, and digital to analog converter 318). In some embodiments, the output of VCO 430 signal 431 (e.g., electrical signal) may then be amplified by a TIA 424 and converted via ADC 426 into a digital feedback frequency 425 to be provided back to the digital TDC 310 of the electronic components.

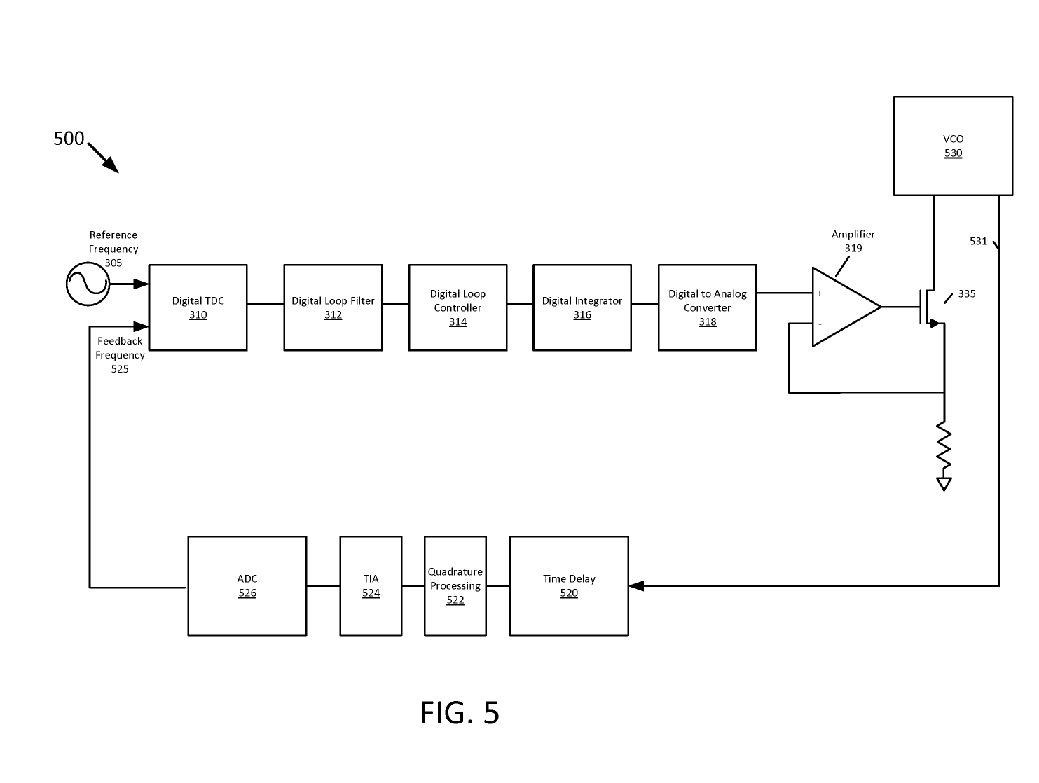

FIG. 5 depicts an example circuit 500 including circuitry to simulate the operation of photonics components according to embodiments of the present disclosure. The circuit 500 may include the same or similar electronic components as circuit 300 of FIG. 3 (e.g., digital TDC 310, digital loop filter 312, digital loop controller 314, digital integrator 316, and digital to analog converter 318). As depicted in FIG. 5, the circuit 500 includes a VCO 530, a time delay 520, and a quadrature processing circuit 522. Additionally, it should be noted that a current controlled oscillator (CCO) may also be used in some embodiments in place of, or in addition to, VCO 530.

As described above, the VCO 530 produces an electrical signal 531 with a frequency that is dependent on (e.g., proportional) the voltage or current generated from the output of the electronic components. In some examples, the electrical signal 531 generated by the VCO may be provided to additional electronic components or circuits that apply one or more functions (e.g., linear functions) to the electrical signal 531. For example, as depicted in FIG. 5, the circuits may introduce a time delay 520 and a quadrature processing circuit 522. The time delay 520 may include a circuit that receives an electrical signal 531 and outputs the signal with a certain temporal delay. Accordingly, the time delay 520 may output a time delayed version of the electrical signal 531 received from the VCO 530. The time delay 520 may thus electrically simulate the time delay produced by an MZI (e.g., MZI 320 of FIG. 3) for an optical signal. The quadrature processing circuit 522 may then generate a resulting oscillating signal from the combination of the original electrical signal from the VCO 530 and the time delayed signal from the time delay circuit 520. In some embodiments, the quadrature processing circuit 522 can be a multiplication function, which results in the difference (and sum) of frequencies between the original electrical signal from the VCO 530 and time delayed signal from the time delay circuit. For example, referring to FIG. 2 (delta fR(t)), this circuit simulates the mixer properties of the photodiode that it is replacing. The resulting signal from the quadrature processing circuit 522 may mirror the beat frequency produced by a PD. Therefore, the VCO 530, the time delay 520, and the quadrature processing circuit 522 may combine to electrically simulate the photonics components (e.g., at least laser diode 330, MZI, 320, and PD 322) by producing an electronic beat frequency from the output of the integrated electronic components (e.g., digital TDC 310, digital loop filter 312, digital loop controller 314, digital integrator 316, and digital to analog converter 318). The output of the quadrature processing circuit 522 may then be amplified by a TIA 524 after which the electrical signal is converted into a digital feedback frequency 525 to be provided back to the digital TDC 310 of the electronic components.

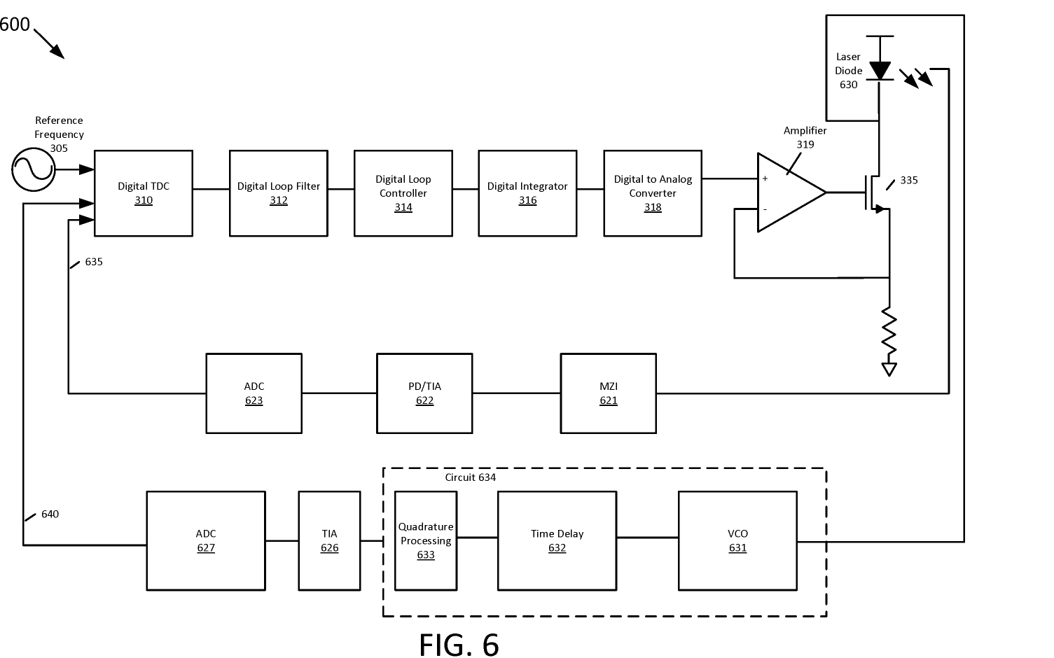

FIG. 6 depicts an example circuit 600 including circuitry to simulate operation of photonics components according to embodiments of the present disclosure. The circuit 600 may include the same or similar electronic components as circuit 300 of FIG. 3 (e.g., digital TDC 310, digital loop filter 312, digital loop controller 314, digital integrator 316, digital to analog converter 318, and amplifier 319). Additionally, the circuit 600 may also include components laser diode 630, MZI 621, PD/TIA 622, and ADC 623. The circuit 600 may also include a circuit 634 that includes VCO 631, a time delay 632, and a quadrature processing circuit 633. As depicted in FIG. 6, the VCO 631 may be coupled between the transistor at the output of the electronic components and a resistor at ground. Accordingly, the VCO 631 may be voltage controlled while in other examples the VCO 631 may be current controlled or voltage controlled. Although depicted as being duplicated, in some examples, the TIA of PD/TIA 622 and ADC 623 to produce feedback signal 635 and TIA 626 and ADC 627 to produce feedback signal 640 may be a single circuit receiving both or either of the signals output from the circuit 634 or the PD/TIA 622.

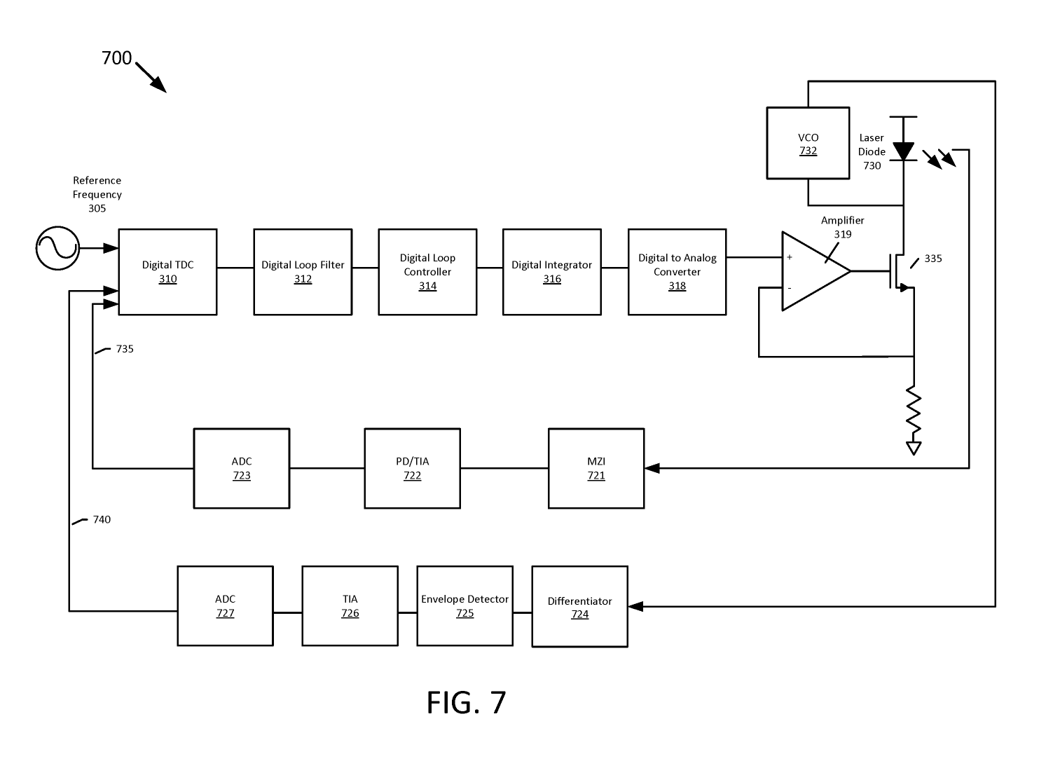

FIG. 7 example circuit including circuitry to simulate operation of photonics components in parallel with the photonics components according to embodiments of the present disclosure. The circuit 700 may include the same or similar electronic components as circuit 300 of FIG. 3 (e.g., digital TDC 310, digital loop filter 312, digital loop controller 314, digital integrator 316, and digital to analog converter 318). Additionally, the circuit 700 may include both photonics components (e.g., laser diode 730, MZI 721, and PD 722) as well as circuits for mimicking the photonics components (e.g., differentiator 724 and envelope detector 725). Although depicted as being duplicated, in some examples, the TIA of PD/TIA 722 and ADC 723 to produce feedback signal 735 and TIA 726 and ADC 727 to produce feedback signal 740 may be a single circuit receiving both or either of the signals output from the envelope detector 725 or the PD 722.

As depicted in FIG. 7, the differentiator 724 and 725 may be incorporated along with the VCO 732, MZI 721, and PD 722. Therefore, both circuits can be used for operation of the phase-locked loop. For example, the laser diode 730, MZI 722, and PD 722 may be used during normal operation of the circuit 700 (e.g., when incorporated in a LIDAR system for range and velocity detection of a target) while the VCO 732, differentiator 724, and envelope detector 725 may be used to test, monitor, optimize, or diagnose operation of the electronic components. In some examples, the circuit 700 may include a switch or controller to select which circuit is to be used at a given time. Laser diode 730, MZI 721, and PD 722 may operate as described above with respect to FIG. 3. VCO 732, differentiator 724, and envelope detector 725 may operate as described above with respect to FIG. 4.

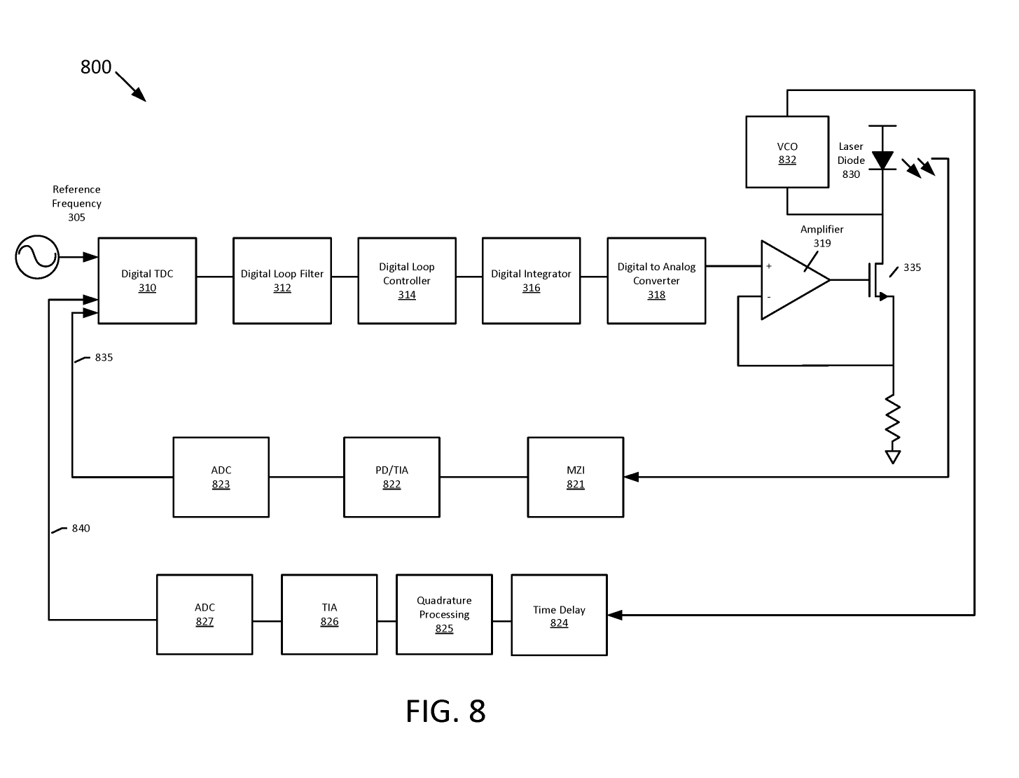

FIG. 8 example circuit including circuitry to simulate operation of photonics components in parallel with the photonics components according to embodiments of the present disclosure. The circuit 800 may include the same or similar electronic components as circuit 300 of FIG. 3 (e.g., digital TDC 310, digital loop filter 312, digital loop controller 314, digital integrator 316, and digital to analog convert 318). Additionally, the circuit 800 may include both photonics components (e.g., laser diode 830, MZI 821, and PD 822) as well as circuits for mimicking the photonics components (e.g., time delay 824 and quadrature processing circuit 825). Although depicted as being duplicated, in some examples, the TIA of PD/TIA 822 and ADC 823 to produce feedback signal 835 and TIA 826 and ADC 827 to produce feedback signal 840 may be a single circuit receiving both or either of the signals output from the quadrature processing circuit 825 or the PD 822.

As depicted in FIG. 8, the VCO 832, time delay 724 and quadrature processing circuit 825 may be incorporated along with the laser diode 830, MZI 721, and PD 722. Therefore, both circuits can be used for operation of the phase-locked loop. For example, the laser diode 830, MZI 822, and PD 822 may be used during normal operation of the circuit 800 (e.g., when incorporated in a LIDAR system for range and velocity detection of a target) while the VCO 832, time delay 824, and quadrature processing 825 may be used to test, monitor, optimize, or diagnose operation of the electronic components. In some examples, the circuit 800 may include a switch or controller to select which circuit is to be used at a given time. Laser diode 830, MZI 821, and PD 822 may operate as described above with respect to FIG. 3. VCO 832, time delay 824, and quadrature processing circuit 825 may operate as described above with respect to FIG. 5.

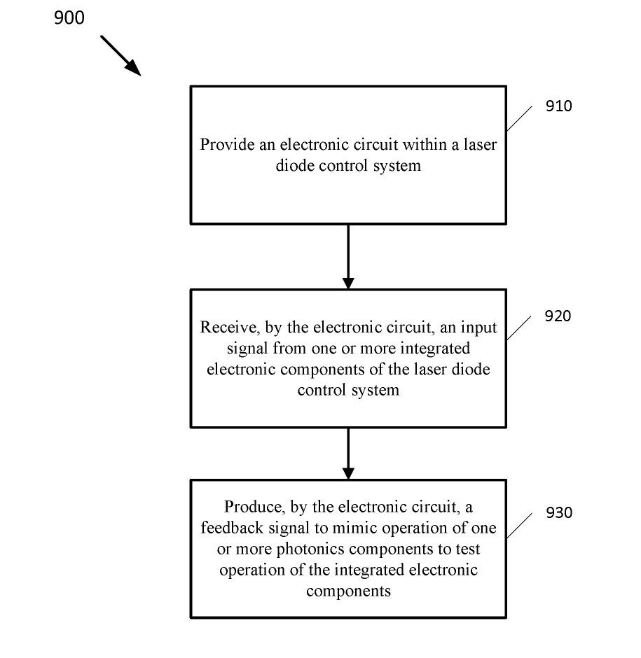

FIG. 9 is a flowchart illustrating a method 900 of operating a circuit including photonics mimicking circuitry to test electronic components of the circuit, according to some embodiments.

Method 900 begins at block 902, where an electronic circuit is provided within a laser diode control system. The electronic circuit may be one or more electrical components to mimic operation of a photonics circuit. In some embodiments, the electronic circuit includes a component to generate an oscillating signal based on an output from integrated electronic components of the laser diode control system. For example, the electronic circuit may include VCO or a CCO to generate the oscillating electrical signal. The electronic circuit further includes a component to apply a time delay or phase shift to the oscillating signal (e.g., a time delay circuit or a differentiator). The electronic circuit may further include a component to generate an output from the combination of the oscillating signal and the delayed oscillating signal.

At block 904, the electronic circuit receives an input signal from one or more integrated electronic components of the laser diode control system. As discussed above, the electronic circuit may receive the input signal from electronic components that are integrated into the laser diode control system (e.g., on-chip). The integrated electronic components may digitally manage and control the output signal of the laser diode control system based on a reference frequency and a feedback frequency. During typical operation of the laser diode control system, the feedback frequency may be generated from the optical beam generated from a laser diode which is delayed by an MZI and then combined back with the original optical beam to produce a beat frequency at a PD. However, during a test or monitoring of the integrated electronic components, the electronic circuit receives and processes the input signal from the integrated electronic components.

At block 906, the electronic circuit generates a feedback signal to mimic operation of one or more photonics components to test operation of the integrated electronic components of the phase locked loop. For example, the electronic circuit produces an oscillating electrical signal from the input signal (e.g., voltage or current dependent), applies a delay or phase shift to the oscillating signal, and generates an output signal via a combination of the original signal and the delayed or shifted signal. Thus, the electronic circuit mimics the output of the photonics circuit via analogous electrical circuits. Accordingly, the electronic circuit may be used to test, monitor, or otherwise optimize the integrated electronic components both prior to incorporating the photonics components and after incorporating the photonics components. In some embodiments, the photonics components are integrated into the phase-locked loop after testing via the electronic circuit has validated the functionality of the one or more integrated electronic components.

The preceding description sets forth numerous specific details such as examples of specific systems, components, methods, and so forth, in order to provide a thorough understanding of several examples in the present disclosure. It will be apparent to one skilled in the art, however, that at least some examples of the present disclosure may be practiced without these specific details. In other instances, well-known components or methods are not described in detail or are presented in simple block diagram form in order to avoid unnecessarily obscuring the present disclosure. Thus, the specific details set forth are merely exemplary. Particular examples may vary from these exemplary details and still be contemplated to be within the scope of the present disclosure.

Any reference throughout this specification to “one example” or “an example” means that a particular feature, structure, or characteristic described in connection with the examples are included in at least one example. Therefore, the appearances of the phrase “in one example” or “in an example” in various places throughout this specification are not necessarily all referring to the same example.

Although the operations of the methods herein are shown and described in a particular order, the order of the operations of each method may be altered so that certain operations may be performed in an inverse order or so that certain operation may be performed, at least in part, concurrently with other operations. Instructions or sub-operations of distinct operations may be performed in an intermittent or alternating manner.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize. The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Furthermore, the terms “first,” “second,” “third,” “fourth,” etc. as used herein are meant as labels to distinguish among different elements and may not necessarily have an ordinal meaning according to their numerical designation.

What is claimed is:

1. An apparatus comprising:
a laser configured to output a beam;
a modulator operatively coupled to the laser, the modulator configured to frequency modulate the beam;
an interferometer operatively coupled to the laser, the interferometer configured to measure deviations in the frequency modulation of the beam; and
correction circuitry configured to:
generate a correction signal based on the deviations in the frequency modulation of the beam; and
apply the correction signal to the modulator to adjust the frequency modulation of the beam based at least in part on the deviations in the frequency modulation of the beam.

2. The apparatus of claim 1, wherein the interferometer is further configured to:
apply a delay to the beam to generate a delayed beam.

3. The apparatus of claim 2, further comprising:
a photodetector configured to combine the delayed beam and the beam to generate a feedback signal that indicates the deviations in the frequency modulation of the beam.

4. The apparatus of claim 3, wherein the frequency modulation of the beam indicates a chirp rate of the beam and the feedback signal indicates deviations in the chirp rate of the beam.

5. The apparatus of claim 3, further comprising:
a transimpedance amplifier configured to amplify the feedback signal.

6. The apparatus of claim 3, wherein the correction circuitry generates the correction signal based on the feedback signal and a reference signal.

7. The apparatus of claim 6, wherein the correction circuitry comprises a digital loop controller and wherein the correction signal causes the modulator to change a chirp rate of the laser to adjust the frequency modulation of the beam.

8. The apparatus of claim 1, further comprising:
a waveguide configured to operatively couple the laser and the interferometer.

9. The apparatus of claim 1, wherein in response to the correction signal, the modulator is configured to:
generate an increasing or decreasing ramp current; and
provide the increasing or decreasing ramp current to the laser.

10. The apparatus of claim 1, wherein the interferometer comprises a Mach–Zehnder interferometer.

11. A method comprising:
outputting, by a laser, a beam;
frequency modulating, by a modulator, the beam;
measuring, by an interferometer, deviations in the frequency modulation of the beam;
generating a correction signal based on the deviations in the frequency modulation of the beam; and
applying the correction signal to the modulator to adjust the frequency modulation of the beam based at least in part on the deviations in the frequency modulation of the beam.

12. The method of claim 11, further comprising:
applying, by the interferometer, a delay to the beam to generate a delayed beam.

13. The method of claim 12, further comprising:
combining, by a photodetector, the delayed beam and the beam to generate a feedback signal that indicates the deviations in the frequency modulation of the beam.

14. The method of claim 13, wherein the frequency modulation of the beam indicates a chirp rate of the beam and the feedback signal indicates deviations in the chirp rate of the beam.

15. The method of claim 13, further comprising:
amplifying the feedback signal.

16. The method of claim 13, wherein the correction signal is generated based on the feedback signal and a reference signal.

17. The method of claim 16, wherein the correction signal causes the modulator to change a chirp rate of the laser to adjust the frequency modulation of the beam.

18. The method of claim 11, wherein the laser and the interferometer are operatively coupled using a waveguide.

19. The method of claim 11, further comprising:
in response to the correction signal:
generating, by the modulator, an increasing or decreasing ramp current; and
providing the increasing or decreasing ramp current to the laser.

20. The method of claim 11, wherein the interferometer comprises a Mach–Zehnder interferometer.
